(19) United States
(12) Patent Application Publication
(10) Pub. No.: US 2002/0163382 A1
(43) Pub. Date: Nov. 7, 2002

(54) High dynamic range amplification circuit

(75) Inventors: Taisto Soikkeli, Kiiminki (FI); Markku Tiihonen, Oulu (FI)

Correspondence Address: David A Hall, Heller Ehrman White & McAuliffe LLP, 4350 La Jolla Village Drive, 7th Floor, San Diego, CA, 92122-1246, US

(73) Assignee: ADC Telecommunications, Inc.

(21) Appl. No.: 09/850,294

(22) Filed: May 7, 2001

(51) Int. Cl. H03F 1/14; H03F 3/68

(52) U.S. Cl. 330/51; 330/295

(57) ABSTRACT

An integrated circuit for amplifying a signal and having an input that receives the signal and an output that outputs an amplified signal is provided. The integrated circuit has a first switch having at least two outputs. The first switch is coupled to the input of the integrated circuit and receives the signal from the input of the integrated circuit. In addition, the integrated circuit has a second switch having at least two inputs. The second switch is coupled to the output of the integrated circuit and transmits the amplified signal to the output of the integrated circuit. The integrated circuit has a first transistor that has a noise figure, an input coupled to one of the outputs of the first switch, and an output coupled to one of the inputs of the second switch. Moreover, the integrated circuit has a second transistor in parallel with the first transistor. The second transistor has a noise figure that is less than the noise figure of the first transistor, an input coupled to the other output of the first switch, and an output coupled to the other input of the second switch. The first and second switches simultaneously selectively couple one of the first and second transistors to the input and output of the integrated circuit based on the level of the signal received at the input of the integrated circuit.

### TECHNICAL FIELD

The present invention relates generally to the field of electronic circuits and, in particular, to an integrated circuit that amplifies a signal and that is switchable between a mode for amplifying low signal levels and a mode for amplifying higher signal levels.

### BACKGROUND

Amplifiers increase the level of signals. For example, amplifiers increase the level of radio frequency (RF) signals that are received by an antenna before the RF signals are transmitted to a radio receiver. When amplifying a signal, it is important that the noise introduced by the amplifier be low relative to the level of the incoming signal so that the noise does not interfere with the incoming signal. Therefore, amplifiers that are used to amplify relatively high signal levels often can have higher noise figures than amplifiers that are used to amplify relatively low signal levels.

Frequently, the level of the incoming signal varies. For example, the level of the incoming signal can vary because the distance between a signal receiver and the signal source varies, e.g., cellular telephone handsets, automobile radios, etc. When the level of the incoming signal varies, the noise figure of the amplifier may be too high for relatively low signal levels, if the amplifier has been selected to amplify relatively high signal levels. On the other hand, if the amplifier has been selected to amplify relatively low signal levels, variation in the incoming signal level may result in signal levels that exceed the compression point of the amplifier. When the compression point is exceeded an amplifier loses its linearity; the gain of the amplifier decreases; and distortion starts to appear in the output.

For the reasons stated above, and for other reasons stated below which will become apparent to those skilled in the art upon reading and understanding the present specification, there is a need in the art for amplifiers that can amplify incoming signals over a wide dynamic range such that the compression point of the amplifier is not exceeded when incoming signal levels are relatively high and the noise figure of the amplifier is low enough so as not to degrade the incoming signal when incoming signal levels are relatively low.

### SUMMARY

The above-mentioned problems with amplifying incoming signals over a wide dynamic range, e.g., amplifier noise being too high for relatively low signal levels and amplifier compression points being exceeded for relatively high signal levels, and other problems are addressed by embodiments of the present invention and will be understood by reading and studying the following specification. Embodiments of the present invention provide an integrated circuit that amplifies an input signal with a high dynamic range. The noise figure of the integrated circuit is low enough so that the noise introduced by the circuit does not to interfere with the input signal when the level of the input signal is low. The compression point of the integrated circuit is high enough so that the input signal does not exceed the compression point when the level of the input signal is high.

More particularly, in one embodiment, an integrated circuit for amplifying a signal and having an input that receives the signal and an output that outputs an amplified signal is provided. The integrated circuit has a first switch having at least two outputs. The first switch is coupled to the input of the integrated circuit and receives the signal from the input of the integrated circuit. In addition, the integrated circuit has a second switch having at least two inputs. The second switch is coupled to the output of the integrated circuit and transmits the amplified signal to the output of the integrated circuit. The integrated circuit has a first transistor that has a noise figure, an input coupled to one of the outputs of the first switch, and an output coupled to one of the inputs of the second switch. Moreover, the integrated circuit has a second transistor in parallel with the first transistor. The second transistor has a noise figure that is less than the noise figure of the first transistor, an input coupled to the other output of the first switch, and an output coupled to the other input of the second switch. The first and second switches simultaneously selectively couple one of the first and second transistors to the input and output of the integrated circuit based on the level of the signal received at the input of the integrated circuit.

### BRIEF DESCRIPTION OF THE DRAWINGS

FIG. 1 is a block diagram of an embodiment of the present invention.

FIG. 2 is a block diagram of another embodiment of the present invention.

FIG. 3 is a schematic circuit diagram of another embodiment of the present invention.

FIG. 4 is an illustration of an embodiment of a microelectromechanical switch that is used in various embodiments of the present invention.

### DETAILED DESCRIPTION

In the following detailed description, reference is made to the accompanying drawings that form a part hereof, and in which is shown by way of illustration specific illustrative embodiments in which the invention may be practiced. These embodiments are described in sufficient detail to enable those skilled in the art to practice the invention, and it is to be understood that other embodiments may be utilized and that logical, mechanical and electrical changes may be made without departing from the spirit and scope of the present invention. The following detailed description is, therefore, not to be taken in a limiting sense.

Embodiments of the present invention provide an integrated circuit for amplifying an input signal with a high dynamic range. High dynamic range refers to a signal whose anticipated levels range from low levels that may require an amplifying component with a noise figure low enough so that the noise does not interfere with the input signal to high levels that exceed the compression point of the amplifying component. When the signal level is relatively low, the input signal is switched to a first transistor whose noise figure is low enough so that the noise introduced by the first transistor does not to interfere with the input signal. When the signal level is relatively high, the input signal is switched to a second transistor that has a noise figure that is somewhat greater than the noise figure of first transistor, but not enough so that the noise introduced by the second transistor interferes with the higher-level input signal, and a compression point that is greater than the compression point of the first transistor. The compression point of second transistor is such that the anticipated level of the input signal does not exceed the compression point.

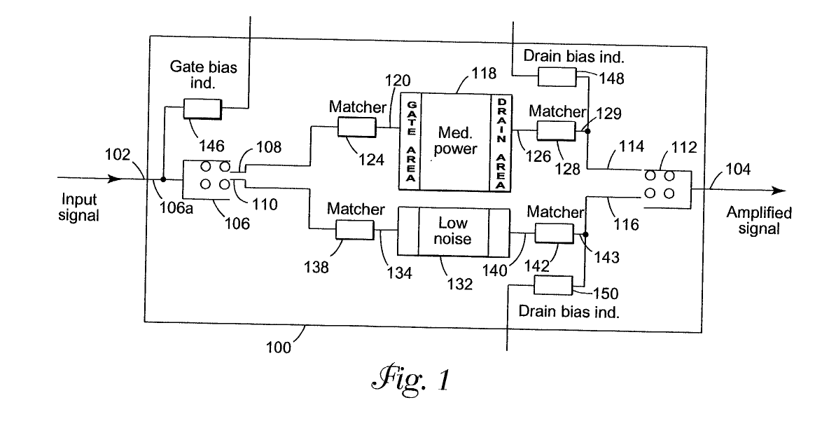

An embodiment of the present invention is demonstrated in FIG. 1 by integrated circuit 100. Integrated circuit 100 has input 102 for receiving an input signal and output 104 for outputting an amplified signal. Integrated circuit 100 has microelectromechanical switch 106 that is coupled to input 102 and that receives the input signal from input 102. Microelectromechanical switch 106 includes outputs 108 and 110. Integrated circuit 100 includes microelectromechanical switch 112 that is coupled to output 104 and that transmits the amplified signal to output 104. Microelectromechanical switch 112 includes inputs 114 and 116.

Integrated circuit 100 includes field effect transistor 118 that has input 120 coupled to output 108 of microelectromechanical switch 106 via impedance matcher 124, as shown in FIG. 1. Impedance matcher 124 matches the impedance of input 102 of integrated circuit 100 to the impedance of input 120 of field effect transistor 118. In one embodiment, impedance matcher 124 includes an LC circuit. In another embodiment, impedance matcher 124 includes an LC circuit and a stripline. Field effect transistor 118 has output 126 coupled to input 114 of microelectromechanical switch 112 via impedance matcher 128. Impedance matcher 128 matches the impedance of output 126 of field effect transistor 118 to the impedance of output 104 of integrated circuit 100. In one embodiment, impedance matcher 128 includes an LC circuit. In another embodiment, impedance matcher 128 includes an LC circuit and a stripline.

Integrated circuit 100 includes field effect transistor 132 that has input 134 coupled to output 110 of microelectromechanical switch 106 via impedance matcher 138, as shown in FIG. 1. Impedance matcher 138 matches the impedance of input 102 to the impedance of input 134 of field effect transistor 132. In one embodiment, impedance matcher 138 includes an LC circuit. In another embodiment, impedance matcher 138 includes an LC circuit and a stripline. Field effect transistor 132 has output 140 coupled to input 116 of microelectromechanical switch 112 via impedance matcher 142. Impedance matcher 142 matches the impedance of output 140 of field effect transistor 132 to the impedance of output 104. In one embodiment, impedance matcher 142 includes an LC circuit. In another embodiment, impedance matcher 142 includes an LC circuit and a stripline.

The gates of field effect transistors 118 and 132 are dc biased using gate bias inductor 146. Gate bias inductor 146 is coupled to input 106a of microelectromechanical switch 106, as shown in FIG. 1. The drains of field effect transistors 118 and 132 are respectively dc biased using drain bias inductors 148 and 150. Drain bias inductor 148 is coupled to input 114 of microelectromechanical switch 112 and output 129 of impedance matcher 128, as shown in FIG. 1. Drain bias inductor 150 is coupled to input 116 of microelectromechanical switch 112 and output 143 of impedance matcher 142, as shown in FIG. 1.

Field effect transistors 118 and 132 each have a noise figure defined as the signal-to-noise power ratio at input 102 divided by the signal-to-noise power ratio at output 104. The noise figure of field effect transistor 132 is less than the noise figure of field effect transistor 118. In one embodiment, the noise figure of field effect transistor 132 is at least 1 dB less than the noise figure of field effect transistor 118. In one embodiment, field effect transistor 132 has a gain that is less than the gain of field effect transistor 118. In another embodiment, field effect transistor 132 has a gain that is equal to the gain of field effect transistor 118.

Moreover, field effect transistor 118 has a higher compression point than field effect transistor 132. The compression point is the value of the input power at which the amplification is no longer linear and consequently where the gain starts to decrease. In one embodiment, the compression point of field effect transistor 118 is high enough so that the input signal level falls within the linear operating range of field effect transistor 118. In another embodiment, the compression point of field effect transistor 118 is as much as 20 dB greater than the compression point of field effect transistor 132.

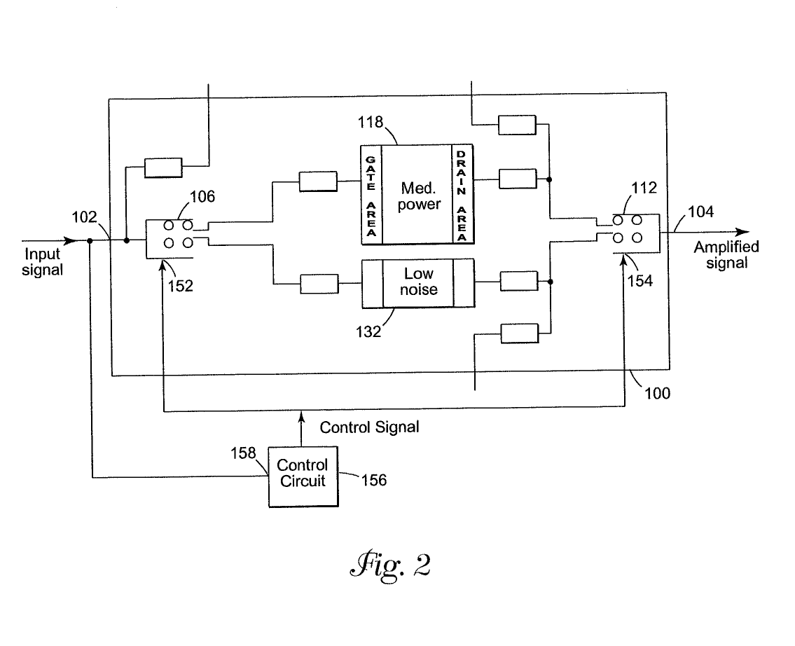

In one embodiment, as demonstrated in FIG. 2, microelectromechanical switches 106 and 112 respectively have control inputs 152 and 154 that receive a control signal from control circuit 156. Control circuit 156 has input 158 coupled to input 102 of integrated circuit 100. The control signal switches microelectromechanical switches 106 and 112 to simultaneously selectively couple one of field effect transistors 118 and 132 to input 102 and output 104 of integrated circuit 100 based on the level of the input signal.

Note that FIGS. 1 and 2 demonstrate switches 106 and 112 selectively coupling field effect transistor 118 to input 102 and output 104 via output 108 of microelectromechanical switch 106, impedance matcher 124, input 120 and output 126 of field effect transistor 118, impedance matcher 128, and input 114 of microelectromechanical switch 112. Although not shown, microelectromechanical switches 106 and 112 similarly selectively couple field effect transistor 132 to input 102 and output 104 via output 110 of microelectromechanical switch 106, impedance matcher 138, input 134 and output 140 of field effect transistor 132, impedance matcher 142, and input 116 of microelectromechanical switch 112.

In operation, the input signal is received at input 102 of integrated circuit 100 and at input 158 of control circuit 156. Control circuit 156 measures the level of the input signal and compares the measured level of the input signal to a preselected value. Control circuit 156 transmits the control signal to control inputs 152 and 154 respectively of microelectromechanical switches 106 and 112 based on the comparison. The control signal switches microelectromechanical switches 106 and 112 to simultaneously selectively couple one of field effect transistors 118 and 132 to input 102 and output 104 of integrated circuit 100. This enables the input signal to be transmitted to the selected one of field effect transistors 118 and 132, where the input signal is amplified, via microelectromechanical switch 106. The amplified signal is then transmitted to output 104 via microelectromechanical switch 112.

In one embodiment, the preselected value is the compression point of field effect transistor 132. In this embodiment, the input signal is transmitted to field effect transistor 132 when the input signal level is below the compression point of field effect transistor 132. That is, when the input signal level is low enough to be within the linear operating range of field effect transistor 132, the input signal is transmitted to field effect transistor 132 for amplification. When the input signal level exceeds the compression point of field effect transistor 132, the input signal is transmitted to field effect transistor 118 for amplification.

In another embodiment, the preselected value is less than the compression point of field effect transistor 132, e.g., 20 to 30 dB less. In another embodiment, the input signal is transmitted to field effect transistor 118 for amplification when the input signal level is high enough to produce intermodulation that is unacceptable for a given application, e.g., in cellular base stations or repeater systems where the input to the receiver contains more than one signal because there are several mobile phones inside a cell.

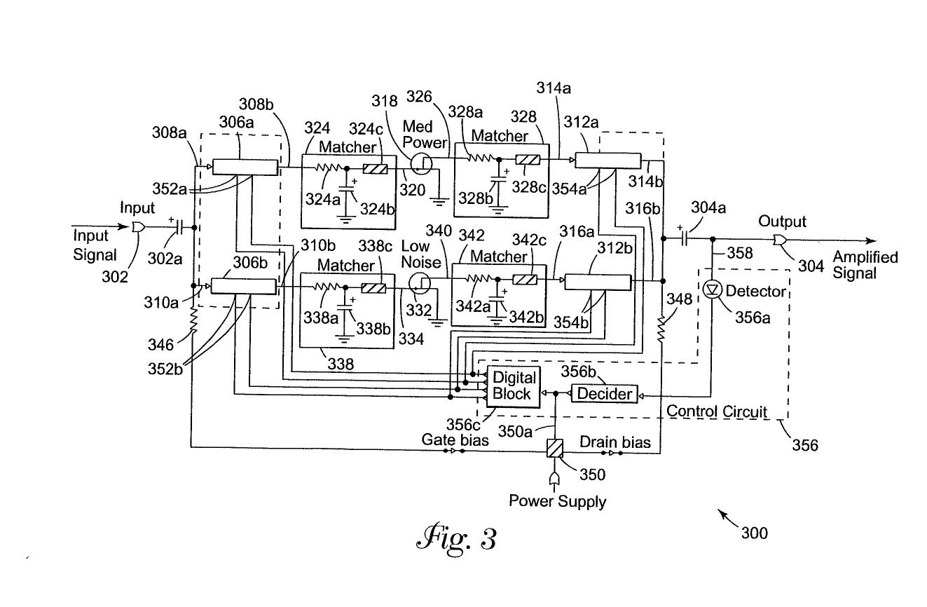

Another embodiment of the present invention is demonstrated in FIG. 3 by integrated circuit 300. FIG. 3 is a schematic diagram of integrated circuit 300. Integrated circuit 300 has input 302 for receiving the input signal and output 304 for outputting an amplified signal. Integrated circuit 300 has microelectromechanical switches 306a and 306b that are coupled to input 302 via capacitor 302a. Microelectromechanical switches 306a and 306b receive the input signal from input 302. Microelectromechanical switch 306a includes input and output 308a and 308b. Microelectromechanical switch 306b includes input and output 310a and 310b.

Integrated circuit 300 includes microelectromechanical switches 312a and 312b that are coupled to output 304 via capacitor 304a. Microelectromechanical switches 312a and 312b transmit the amplified signal to output 304. Microelectromechanical switch 312a includes input and output 314a and 314b. Microelectromechanical switch 312b includes input and output 316a and 316b.

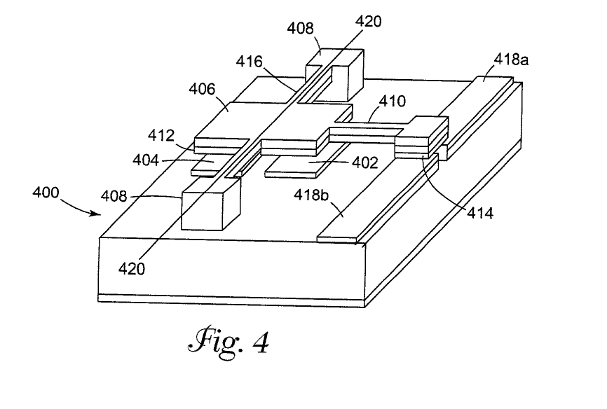

In one embodiment, microelectromechanical switch 400, illustrated in FIG. 4, is used for microelectromechanical switches 306a, 306b, 312a, and 312b. Microelectromechanical switch 400 includes pull electrode 402 and push electrode 404. Microelectromechanical switch 400 includes upper electrode 406 that is pivotally attached to anchors 408. Upper electrode 406 includes lever 410 that is integral with upper electrode 406. Upper electrode 406 also includes insulator 412 and contact 414, as shown in FIG. 4. Upper electrode 406 is biased in the open position (i.e., the position shown) by torsion spring 416. Microelectromechanical switch 400 includes line segments 418a and 418b. Line segment 418a is coupled to one of inputs 308a, 310a, 314a, and 316a of microelectromechanical switches 306a, 306b, 312a, and 312b, respectively, while line segment 418b is coupled to one of outputs 308b, 310b, 314b, and 316b of microelectromechanical switches 306a, 306b, 312a, and 312b, respectively.

To close microelectromechanical switch 400, microelectromechanical switch 400 receives control signals at pull electrode 402 and push electrode 404 that cause upper electrode 406 to pivot about axis 420. The pivoting action brings contact 414 into contact with line segments 418a and 418b to close microelectromechanical switch 400, thereby electrically coupling line segments 418a and 418b. This, in turn, couples one of input 308a and output 308b, input 310a and output 310b, input 314a and output 314b, and input 316a and output 316b of microelectromechanical switches 306a, 306b, 312a, and 312b, respectively. To open microelectromechanical switch 400, the control signals are removed from pull electrode 402 and push electrode 404, and torsion spring 416 pivots upper electrode 406 about axis 420 into the open position illustrated in FIG. 4.

Microelectromechanical switches 306a, 306b, 312a, and 312b respectively have control inputs 352a, 352b, 354a, and 354b that receive a control signal from control circuit 356, as shown in FIG. 3. Note that each of control inputs 352a, 352b, 354a, and 354b includes a pair of control inputs. In embodiments where microelectromechanical switch 400, illustrated in FIG. 4, is used for microelectromechanical switches 306a, 306b, 312a, and 312b, one of the pair of inputs is coupled to pull electrode 402 and the other input to push electrode 404. In other embodiments, each of control inputs 352a, 352b, 354a, and 354b can include a single control input or more than a pair of control inputs, depending upon the type of microelectromechanical switch being used.

Control circuit 356 has input 358 coupled to output 304 of integrated circuit 300. Control circuit 356 includes diode detector 356a coupled to decider 356b. Decider 356b is coupled to digital-block 356c. Digital-block 356c includes the logic for switching microelectromechanical switches 306a, 306b, 312a, and 312b. In one embodiment, decider 356b and digital-block 356c are formed on the same chip as integrated circuit 300, and diode detector 356a is separate from integrated circuit 300, as demonstrated in FIG. 3. In another embodiment, control circuit 356 is formed on the same chip as integrated circuit 300. In another embodiment, control circuit 356 is separate from integrated circuit 300.

Integrated circuit 300 includes field effect transistor 318 that has input 320 coupled to output 308b of microelectromechanical switch 306a via impedance matcher 324, as shown in FIG. 3. Impedance matcher 324 matches the impedance of input 302 of integrated circuit 300 to the impedance of input 320 of field effect transistor 318. Impedance matcher 324 includes inductor 324a, capacitor 324b, and stripline 324c, coupled as shown in FIG. 3. Field effect transistor 318 has output 326 coupled to input 314a of microelectromechanical switch 312a via impedance matcher 328. Impedance matcher 328 matches the impedance of output 326 of field effect transistor 318 to the impedance of output 304 of integrated circuit 300. Impedance matcher 328 includes inductor 328a, capacitor 328b, and stripline 328c, coupled as shown in FIG. 3.

Integrated circuit 300 includes field effect transistor 332 that has input 334 coupled to output 310b of microelectromechanical switch 306b via impedance matcher 338, as shown in FIG. 3. Impedance matcher 338 matches the impedance of input 302 to the impedance of input 334 of field effect transistor 332. Impedance matcher 338 includes inductor 338a, capacitor 338b, and stripline 338c, coupled as shown in FIG. 3. Field effect transistor 332 has output 340 coupled to input 316a of microelectromechanical switch 312b via impedance matcher 342. Impedance matcher 342 matches the impedance of output 340 of field effect transistor 332 to the impedance of output 304. Impedance matcher 342 includes inductor 342a, capacitor 342b, and stripline 342c, coupled as shown in FIG. 3.

Field effect transistors 318 and 332 each have a noise figure defined as the signal-to-noise power ratio at input 302 divided by the signal-to-noise power ratio at output 304. The noise figure of field effect transistor 332 is less than the noise figure of field effect transistor 318. In one embodiment, the noise figure of field effect transistor 332 is at least 1dB less than the noise figure of field effect transistor 318. In one embodiment, field effect transistor 332 has a gain that is less than the gain of field effect transistor 318. In another embodiment, field effect transistor 332 has a gain that is equal to the gain of field effect transistor 318.

Moreover, field effect transistor 318 has a higher compression point than field effect transistor 332. In one embodiment, the compression point of field effect transistor 318 is high enough so that the input signal level falls within the linear operating range of field effect transistor 318. In another embodiment, the compression point of field effect transistor 318 is as much as 20 dB greater than the compression point of field effect transistor 332.

The gates of field effect transistors 318 and 332 are dc biased using gate bias inductor 346. Gate bias inductor 346 is coupled to inputs 308a and 310a of microelectromechanical switches 306a and 306b, respectively, as shown in FIG. 3. The drains of field effect transistors 318 and 332 are dc biased using drain bias inductor 348. Drain bias inductor 348 is coupled to outputs 314b and 316b of microelectromechanical switches 312a and 312b, respectively, as shown in FIG. 3.

Power supply 350 supplies the respective dc bias voltages for the gates and drains of field effect transistors 318 and 332. Power supply 350 is coupled to gate bias inductor 346 and drain bias inductor 348. Power supply 350 is also coupled to the output of decider 356b (also the input of digital block 356c) by bias-control line 350a.

In operation, integrated circuit 300 receives an input signal at input 302. Depending on the how microelectromechanical switches 306a, 306b, 312a, and 312b are set, the signal is transmitted to one of field effect transistors 318 and 332. The respective one of field effect transistors 318 and 332 amplifies the input signal and transmits the amplified signal to output 304 and to input 358 of control circuit 356.

Control circuit 356 receives the amplified signal via input 358 and measures the level of the amplified signal. Control circuit 356 computes the level of the input signal from known gain of the respective one of field effect transistors 318 and 332. Control circuit 356 compares the level of the input signal to a preselected value. In this embodiment, the preselected value is below (e.g., as much as 20 to 30 dB) the compression point of field effect transistor 332.

More specifically, diode detector 356a of control circuit 356 receives the amplified signal, measures the level of the amplified signal, and outputs an indicative signal that indicates the level of the amplified signal. Decider 356b of control circuit 356 receives the indicative signal from diode detector 356a and computes the level of the input signal from known gain of the respective one of field effect transistors 318 and 332. Decider 356b compares the level of the input signal to the preselected value. Decider 356b transmits a control signal, based on the comparison, to power supply 350 to switch the power supply to bias the gate and drain of the appropriate one of field effect transistors 318 and 332.

Decider 356b also transmits the control signal to digital block 356c. Digital block 356c transmits the control signal to one of the pair of microelectromechanical switches 306a and 312a and the pair of microelectromechanical switches 306b and 312b to simultaneously selectively couple the respective one of field effect transistors 318 and 332 to input 302 and output 304. Note that the selected one of field effect transistors 318 and 332 is biased based on the control signal, as described above. Note further that the pair of microelectromechanical switches 306a and 312a couple transistor 318 to input 302 and output 304, and the pair of microelectromechanical switches 306b and 312b couple transistor 332 to input 302 and output 304.

If microelectromechanical switches 306a, 306b, 312a, and 312b are set so that field effect transistor 332 is the respective one of field effect transistors 318 and 332 and the input signal is less than or equal to the preselected value, then field effect transistor 332 is the selected transistor and is used for the amplification. If the input signal level exceeds the preselected value while field effect transistor 332 is being used control circuit 356 switches the input signal to field effect transistor 318 for amplification. If the input signal level decreases below the preselected value while field effect transistor 318 is being used control circuit 356 switches the input signal to field effect transistor 332 for amplification.

### Conclusion

Embodiments of the present invention have been described. The embodiments provide an integrated circuit for amplifying an input signal having a variable level. When the signal level is relatively low, the input signal is switched to a first transistor whose noise figure is low enough so as not to interfere with the input signal. When the signal level is relatively high, the input signal is switched to a second transistor that has a noise figure that is somewhat greater than the first transistor, but not enough to interfere with the higher-level input signal, and a compression point that is greater than the compression point of the first transistor. The compression point of second transistor is such that the compression point is not exceeded by input signal.

Although specific embodiments have been illustrated and described in this specification, it will be appreciated by those of ordinary skill in the art that any arrangement that is calculated to achieve the same purpose may be substituted for the specific embodiment shown. This application is intended to cover any adaptations or variations of the present invention. For example, each of the gates and each of the drains of the field effect transistors can be biased using an individual bias inductor. Moreover, bias inductors 346 and 348 and/or power supply 350 can be separate from integrated circuit 300 instead of forming them on the same chip as integrated circuit 300 as shown in FIG. 3.

What is claimed is:

1. An integrated circuit for amplifying a signal comprising:
an input that receives the signal and an output that outputs an amplified signal;
a first switch that is coupled to the input of the integrated circuit and that receives the signal from the input of the integrated circuit, the first switch having at least two outputs;
a second switch that is coupled to the output of the integrated circuit and that transmits the amplified signal to the output of the integrated circuit, the second switch having at least two inputs;
a first transistor having a noise figure, an input coupled to one of the outputs of the first switch, and an output coupled to one of the inputs of the second switch;
a second transistor in parallel with the first transistor having a noise figure that is less than the noise figure of the first transistor, an input coupled to the other output of the first switch, and an output coupled to the other input of the second switch; and
wherein the first and second switches simultaneously selectively couple one of the first and second transistors to the input and output of the integrated circuit based on the level of the signal received at the input of the integrated circuit.

2. The integrated circuit of claim 1, wherein the first and second switches are microelectromechanical switches.

3. The integrated circuit of claim 1, wherein the first and second switches each have a control input that receives a control signal from a control circuit that is based on the level of the signal received at the input of the integrated circuit, wherein the control signal switches the first and second switches to simultaneously selectively couple one of the first and second transistors to the input and output of the integrated circuit based on the level of the signal received at the input of the integrated circuit.

4. The integrated circuit of claim 1, wherein the first switch comprises a pair of switches, each switch coupled to the input of the integrated circuit, one of the pair of switches having an output coupled to the input of the first transistor, the other of the pair of switches having an output coupled to the input of the second transistor.

5. The integrated circuit of claim 1, wherein the second switch comprises a pair of switches, each switch coupled to the output of the integrated circuit, one of the pair of switches having an input coupled to the output of the first transistor, the other of the pair of switches having an input coupled to the output of the second transistor.

6. The integrated circuit of claim 1, wherein the first and second transistors are field effect transistors.

7. The integrated circuit of claim 1, wherein the first and second transistors each have a gain and the gain of the second transistor is one of less than and equal to the gain of the first transistor.

8. The integrated circuit of claim 1, wherein the first transistor is coupled to the input and output of the integrated circuit when the level of the signal received at the input of the integrated circuit is high and the second transistor is coupled to the input and output of the integrated circuit when the level of the signal received at the input of the integrated circuit is low.

9. The integrated circuit of claim 1, wherein the first and second transistors each have a compression point, and the compression point of the second transistor is less than the compression point of the first transistor.

10. An integrated circuit for amplifying a signal comprising:
an input that receives the signal and an output that outputs an amplified signal;
a first microelectromechanical switch that is coupled to the input of the integrated circuit and that receives the signal from the input of the integrated circuit, the first switch having at least two outputs;
a second microelectromechanical switch that is coupled to the output of the integrated circuit and that transmits the amplified signal to the output of the integrated circuit, the second switch having at least two inputs;
a first field effect transistor having a noise figure, a compression point, an input coupled to one of the outputs of the first microelectromechanical switch, and an output coupled to one of the inputs of the second microelectromechanical switch;
a second field effect transistor in parallel with the first field effect transistor having a noise figure that is less than the noise figure of the first field effect transistor, a compression point that is less than the compression point of the first field effect transistor, an input coupled to the other output of the first microelectromechanical switch, and an output coupled to the other input of the second microelectromechanical switch; and
wherein the first and second microelectromechanical switches simultaneously selectively couple one of the first and second field effect transistors to the input and output of the integrated circuit based on the level of the signal received at the input of the integrated circuit.

11. The integrated circuit of claim 10, wherein the first and second microelectromechanical switches each have a control input that receives a control signal from a control circuit that is based on the level of the signal received at the input of the integrated circuit, wherein the control signal switches the first and second microelectromechanical switches to simultaneously selectively couple one of the first and second field effect transistors to the input and output of the integrated circuit based on the level of the signal received at the input of the integrated circuit.

12. The integrated circuit of claim 10, wherein the first microelectromechanical switch comprises a pair of microelectromechanical switches, each microelectromechanical switch coupled to the input of the integrated circuit, one of the pair of microelectromechanical switches having an output coupled to the input of the first field effect transistor, the other of the pair of microelectromechanical switches having an output coupled to the input of the second field effect transistor.

13. The integrated circuit of claim 10, wherein the second microelectromechanical switch comprises a pair of microelectromechanical switches, each microelectromechanical switch coupled to the output of the integrated circuit, one of the pair of microelectromechanical switches having an input coupled to the output of the first field effect transistor, the other of the pair of microelectromechanical switches having an input coupled to the output of the second field effect transistor.

14. The integrated circuit of claim 10, wherein the first field effect transistor is coupled to the input and output of the integrated circuit when the level of the signal received at the input of the integrated circuit is high and the second field effect transistor is coupled to the input and output of the integrated circuit when the level of the signal received at the input of the integrated circuit is low.

15. An integrated circuit for amplifying a signal comprising:
an input that receives the signal and an output that outputs an amplified signal;
a pair of first microelectromechanical switches that are coupled to the input of the integrated circuit and that receive the signal from the input of the integrated circuit, each of the pair of first microelectromechanical switches having an output;
a pair of second microelectromechanical switches that are coupled to the output of the integrated circuit and that transmit the amplified signal to the output of the integrated circuit, each of the pair of second microelectromechanical switches having an input;
a first field effect transistor having a noise figure, a compression point, an input coupled to the output of one of the pair of first microelectromechanical switches, and an output coupled to the input of one of the pair of second microelectromechanical switches;
a second field effect transistor in parallel with the first field effect transistor having a noise figure that is less than the noise figure of the first field effect transistor, a compression point that is less than the compression point of the first field effect transistor, an input coupled to the output of the other of the pair of first microelectromechanical switches, and an output coupled to the input of the other of the pair of second microelectromechanical switches; and
wherein one of the pair of first microelectromechanical switches and one of the pair of second microelectromechanical switches simultaneously selectively couple one of the first and second field effect transistors to the input and output of the integrated circuit based on the level of the signal received at the input of the integrated circuit.

16. The integrated circuit of claim 15, wherein each of the pair of first microelectromechanical switches and each of the pair of second microelectromechanical switches have a control input that receives a control signal from a control circuit that is based on the level of the signal received at the input of the integrated circuit, wherein the control signal switches one of the pair of first microelectromechanical switches and one of the pair of second microelectromechanical switches to simultaneously selectively couple one of the first and second field effect transistors to the input and output of the integrated circuit based on the level of the signal received at the input of the integrated circuit.

17. The integrated circuit of claim 15, wherein the first field effect transistor is coupled to the input and output of the integrated circuit when the level of the signal received at the input of the integrated circuit is high and the second field effect transistor is coupled to the input and output of the integrated circuit when the level of the signal received at the input of the integrated circuit is low.

18. A method for amplifying a signal comprising:
receiving the signal at an input of the integrated circuit;
switching simultaneously first and second microelectromechanical switches to selectively couple, based on the level of the signal received at the input of the integrated circuit, one of a plurality of transistors to the input and an output of the integrated circuit, wherein the respective transistors have different noise figures;
transmitting the signal from the input of the integrated circuit to the first microelectromechanical switch;
transmitting the signal from the first microelectromechanical switch to the selected one of the plurality of transistors;
amplifying the signal using the selected one of the plurality of transistors;
transmitting the amplified signal from the selected one of the plurality of transistors to the second microelectromechanical switch; and
transmitting the amplified signal to the output of the integrated circuit from the second microelectromechanical switch.

19. The method of claim 18, further comprising receiving simultaneously a control signal at a control input of each of the first and second microelectromechanical switches that is based on the level of the signal received at the input of the integrated circuit and using the control signal to simultaneously switch the first and second microelectromechanical switches.

20. A method for amplifying a signal comprising:
receiving the signal at an input of the integrated circuit;
receiving a control signal simultaneously at a control input of each of a first and second micro electromechanical switch that is based on the level of the signal;
switching simultaneously the first and second microelectromechanical switches, using the control signal, to selectively couple one of a plurality of transistors to the input and an output of the integrated circuit, wherein the respective transistors have different noise figures;
transmitting the signal from the input of the integrated circuit to the first microelectromechanical switch;
transmitting the input signal from the first microelectromechanical switch to the selected one of the plurality of transistors;
amplifying the signal using the selected one of the plurality of transistors;
transmitting the amplified signal from the selected one of the plurality of transistors to the second microelectromechanical switch; and
transmitting the amplified signal to the output of the integrated circuit from the second microelectromechanical switch.
